(19) United States
(12) Patent Application Publication
(10) Pub. No.: US 2011/0248392 A1
(43) Pub. Date: Oct. 13, 2011

(54) Ball-Grid Array Device Having Chip Assembled on Half-Etched metal Leadframe

(75) Inventors: Reynaldo C. Javier, Plano, TX (US); Sreenivasan K. Koduri, Allen, TX (US)

(73) Assignee: Texas Instruments Incorporated, Dallas, TX (US)

(21) Appl. No.: 12/902,306

(22) Filed: Oct. 12, 2010

Related U.S. Application Data
(60) Provisional application No. 61/323,088, filed on Apr. 12, 2010.

(51) Int. Cl. H01L 23/495

(52) U.S. Cl. 257/676; 257/E23.031

(57) ABSTRACT

A ball grid array device (100) based on a metallic leadframe (110) that has the footprint of a BGA package with terminals (112) in a full two-dimensional array, and combines the structure of a leadframe with the function of a substrate. At least one terminal (112a) is at the center of the device bottom. The terminals and leads (111) are made of metal having a greater thickness at the terminals than at the leads. The terminals may have a solderable surface. A semiconductor chip (120) is attached to the leadframe surface opposite the terminals, extending across adjacent leads.

### FIELD OF THE INVENTION

The present invention is related in general to the field of semiconductor devices and processes, and more specifically to the structure and fabrication method of ball-grid array devices having solderable metallic leadframes of two distinct thicknesses.

### DESCRIPTION OF RELATED ART

Semiconductor devices assembled in Ball Grid Array (BGA) packages connect to external parts by metal bumps, usually solder balls, arrayed in a two-dimensional grid of rows and lines. The metal bumps are attached to the BGA package on the outside terminals of the substrate. Currently, BGA packages use insulating substrates made of polymeric or ceramic material. The substrate has at least one metal layer patterned for interconnecting traces; the semiconductor chip, mounted on the inside surface of the substrate, has its contact pads connected to the traces by wire bonds or by metal bumps. The terminals are connected to the traces by metal-filled via holes through the insulating substrate. An example of a BGA package with wire-bonded assembly and thin polymeric substrate with metal-filled via holes can be found in the well-known MicroStar™ package used in hand-held wireless telephones. For making the chip assembly mechanically more robust and protecting chip and bonding wires, BGA devices are commonly packaged in an encapsulation compound, commonly an epoxy-based molding compound.

It is well known that the polymeric and ceramic materials for the substrates together with the fabrication steps of patterning the inside metal layer and preparing the outside terminals with the metal-filled via holes are cost-intensive. It is further well known that BGA devices, especially those with polymeric substrates, are sensitive to moisture and to warping.

For several decades, semiconductor devices with the traditional cantilever leads (dual-in-line devices, quad-flat pack devices, and plastic leaded chip carriers) as well as the devices of the Quad Flat No-Lead (QFN) and Small Outline No-Lead (SON) families have been manufactured with metallic leadframes. In all these devices, the leads for connections to external parts are linearly arranged along the package edges (along two, three, or all four edges); there are no designs of leadframes, which mimic the two-dimensional array of bump terminals required for a BGA package.

### SUMMARY OF THE INVENTION

Applicants recognized that ongoing market trends in semiconductor BGA device applications such as hand-held products and medical applications push for higher device reliability especially in moist environments, while shrinking package sizes and reducing package cost.

In a detailed analysis of the alternatives for reconciling conflicting technical, manufacturing, and cost requirements of semiconductor BGA packages and their current one-metal-layer substrates, applicants discovered that the sensitivity problems for moisture and warping of BGA devices with polymeric substrates, as well as the cost problem of BGA devices with ceramic substrates, can be resolved by designing and manufacturing a BGA device based on a metallic leadframe that has the footprint of a BGA package with terminals in a full two-dimensional array and can readily replace a BGA package with polymeric or ceramic substrates. In a leadframe-based BGA device, the metallic leadframe provides not only the electrically conductive structure of patterned metal, but also the supportive function of a (robust) substrate.

Applicant further discovered that cumbersome traditional BGA problems, such as creating via holes in a substrate, filling the holes with metal, and using underfill metal to relieve the stress on solder balls, can be solved by employing leadframes made from metal sheets, wherein the leads include the original sheet thickness for the terminals and a reduced thickness for the balance of the leads (so-called half-etched leadframes). Furthermore, the terminals can be arranged in an orderly two-dimensional grid array, which extends across the leadframe area and includes the central leadframe area.

In an exemplary BGA embodiment, the semiconductor chip may be non-conductively attached to a flat surface of the leadframe, whereby the chip extends across several adjacent leads for support; the leads may have the terminals, shaped as mesas, on the same surface as the chip, or preferably on the opposite surface. The terminals preferably have a metallurgical surface configuration to be solderable so that solder balls can be attached in a two-dimensional grid array like in a conventional BGA device. Preferably, the terminals are in evenly spaced locations.

Applicants found that the leads of specific BGA leadframes may have to take unconventional configurations to function in common and non-common net assignments so that the terminals fully utilize the total leadframe area including the area under the chip. As an exemplary embodiment, a molded BGA device of a size of about 1.5 by 1.5 mm² has been fabricated, which has a leadframe with 9 terminals arranged in a 3×3 matrix. The terminals are exposed from the encapsulation compound on the bottom surface of the package. In the package center, the semiconductor chip is attached to the leadframe on the surface opposite the terminals, spanning across several adjacent leads, and the chip contact pads are wire-bonded to the leads. Of the leadframe terminals, the 4 corner terminals and 2 of the edge terminals are connected to short leads, which serve as wire stitch pads. The center terminal belongs to an elongated lead extending as tie-bars to opposite edges of the package, where the tie-bar ends serve as wire stitch pads. The package center area located under the chip is thus utilized as a terminal with net assignment. The remaining 2 terminals are each connected to a tie-bar; they extend to two opposite edges and serve as wire stitch pads.

In alternative embodiments, the chip may be flipped and bonded by metal bumps; the bumps may be configured as solder balls, copper pillars, or gold bumps, or other equivalents, and make metallurgical joints to the leads connected to the terminals.

It is a technical advantage of the invention that the leadframe metal may be selected from a group including copper, aluminum, iron-nickel, Kovar™, and other alloys. It is another technical advantage that the starting metal sheet may be half-etched to create different metal thicknesses of the terminals and the remaining leads; as a preferred ratio, the terminal metals may have twice the thickness of the lead metal.

It is another technical advantage that the leadframe surfaces may be prepared with an affinity for adhering to polymeric compounds (for instance by roughening or oxidizing), while the terminal surfaces may be prepared to be solderable (for instance by plating with additional metal layers such as nickel, palladium, and gold).

It is another technical advantage that the leadframe may be half-etched so that the terminals are on the opposite surface as the chip, or on the same surface, or on both surfaces (an opportunity to enable stacking of packages).

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

It should be noted that the Figures herein are not drawn to scale, are schematic, and serve explanatory purposes only.

FIG. 1 illustrates a perspective bottom view of a packaged QFN/SON-type device having a metal leadframe with terminals arranged in a two-dimensional grid array extending across the device area including the central area; a semiconductor chip is attached to and supported by adjacent leads opposite to the terminals.

FIG. 2 illustrates a perspective top view of a packaged QFN/SON-type device having a metal leadframe with leads extending to at least one edge of the device; a semiconductor chip is attached to and supported by adjacent leads, the chip contacts are wire-bonded to the leads. The terminals of the leads are opposite to the attached chip.

FIG. 3 is a side view of a packaged QFN/SON-type device having a metal leadframe with terminals extending to both the bottom and the top device surfaces. The packaging material is considered transparent.

FIG. 4 illustrates a perspective bottom view of a QFN/SON-type leadframe for use in a ball grid array (BGA) device, the leadframe having two metal thicknesses and terminal locations in a full two-dimensional array. A semiconductor chip is attached on the leadframe top surface opposite to the terminals.

FIG. 5A shows a top view of the leadframe of FIG. 4 (before attaching the chip indicated in FIG. 2).

FIG. 5B is a cross section of the leads along line 5B-5B in FIG. 5A.

FIG. 6 depicts a perspective bottom view of the BGA device of FIG. 1; the encapsulation compound is opaque, the terminals and the lead edges are exposed and un-encapsulated by the polymeric compound.

FIG. 7 illustrates a stack assembled with two leadframe-based BGA devices shown in FIG. 3 and attached to a substrate.

### DETAILED DESCRIPTION OF THE PREFERRED EMBODIMENTS

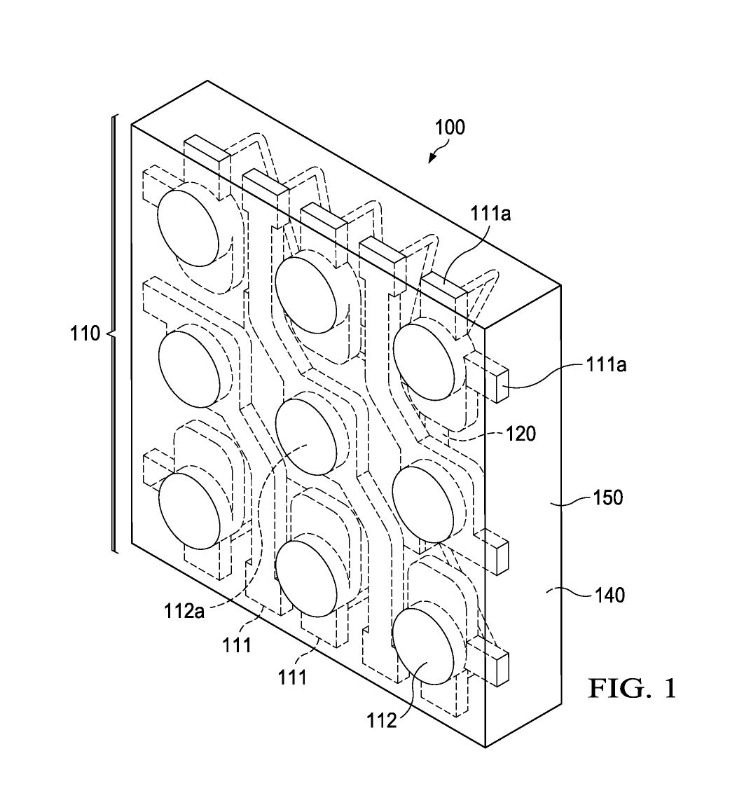

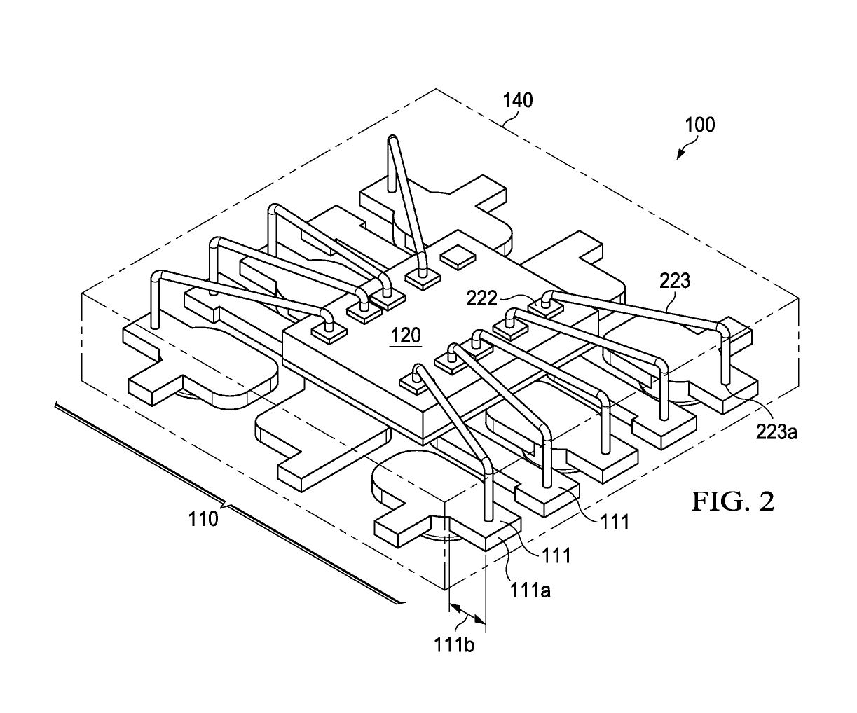

FIG. 1 illustrates a perspective view of the bottom surface of an exemplary semiconductor device, generally designated 100, of the Quad Flat No-lead (QFN) or Small Outline No-Lead (SON) families. The material of package 140 of device 100 is depicted transparent so that the inside structure of device 100 is visible. As indicated by FIG. 1, exemplary device 100 has a hexahedron outline with six plane surfaces; the bottom plane surface is depicted in FIG. 1 and the top plane surface is depicted in FIG. 2. FIG. 1 shows that on the bottom surface the material of package 140 leaves a plurality of terminals 112 un-encapsulated by the package material and thus exposed for electrical connection. As FIG. 1 further shows, terminals 112 are a portion of leadframe 110 of device 100; leadframe 110 is made of a first metal. Leadframe 110 includes a plurality of leads 111 of various shapes.

A semiconductor chip 120 is attached to the top leadframe surface and spans across several adjacent leads. In this configuration, leadframe 110 provides both the structure of leads 111 for electrical interconnection of chip 120 and the function of a robust substrate supporting attached chip 120.

For electrical interconnection, leads 111 are structured to include a plurality of input/output (I/O) terminals 112, which are exposed from the material of package 140 on the bottom side of device 100. As FIG. 1 shows, in exemplary device 100 the terminals 112 are on the bottom surface of leadframe 110, opposite attached chip 120 on the top surface of leadframe 110. Preferably, each lead has one terminal; however in other devices, some leads may have no terminal, and other leads may have more than one terminal. Terminals 112 include a terminal 112a in the center of the leadframe area, underneath the area of chip 120. In other devices, there may be more than one terminal in the central device area. Terminals 112 have a solderable metallurgical surface configuration, preferably a layer of a second metal such as tin or gold.

It should be mentioned that in other devices some leads may have additional terminals on the top surface (onto which the chip is attached) of the leadframe; these additional terminals are also exposed from the package material and thus provide a means to connect device 100 (for instance by soldering) to another device stacked onto device 100.

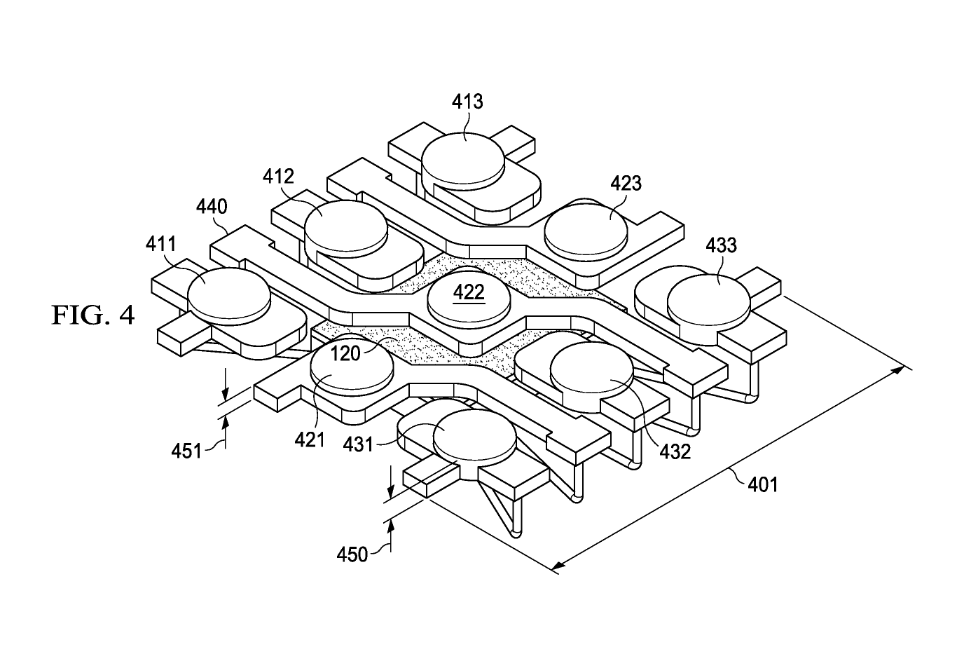

As FIG. 1 shows, the plurality of terminals 112 is arranged in a two-dimensional grid array extending across the device area, including the central area. Preferably, the grid array of the terminals is orderly, and more preferably, the terminals are evenly spaced. However, in other devices the grid array may include depleted positions, or may include other modifications of a monotonous array. Form, outline, and arrangement of the leads are discussed in more detail below in conjunction with FIG. 4.

FIG. 1 indicates that the side surfaces 150 of device 100 show the metallic end faces 111a of the leads, which are became exposed after the frame has been trimmed from the leads. End faces 111a are available for conductive interconnection to external parts such as side-by-side alignment of packages.

To support chip 120 as a robust substrate, leadframe 110 is preferably formed by stamping or etching of a first metal sheet between about 150 and 250 μm; thicker and thinner leadframes may be used. Preferred first metals include copper, copper alloys, iron-nickel alloys, aluminum, and Kovar™. Thereafter, the leadframe is “half-etched” so that the thickness of certain lead portions is reduced by etching (for example by 50%), while the remaining portions preserve the original metal thickness. During the encapsulation process, the reduced thickness portions are replaced by the polymeric material of package 140, significantly stiffening the mechanical strength of the leadframe.

The preferred solderable metallurgical surface configuration of terminals 112 may be achieved by a layer of a solderable second metal such as gold or tin. The metal layer may actually be a stack of layers such as a nickel layer in contact with the first metal, a palladium layer in contact with nickel, and a gold layer in contact with palladium.

FIG. 2 illustrates a perspective view of the top plane surface of the hexahedron-shaped exemplary semiconductor device 100 of the Quad Flat No-lead (QFN) or Small Outline No-Lead (SON) families. The material of package 140 of device 100 is depicted transparent so that the inside structure of device 100 is visible. The plurality of leads 111 of leadframe 110 is viewed in FIG. 2 from the top surface. Attached to the top surface of leadframe 110 is chip 120. In the exemplary device 100 of FIG. 2, an electrically insulating adhesive layer 221 is used to attach chip 120 across adjacent leads 111. In this configuration, leadframe 110 provides the function of a robust substrate supporting attached chip 120; leadframe 110 further provides the structure of leads 111 for electrical interconnection of chip 120. FIG. 2 indicates that certain portions 111b of leads 111 are shaped to operate as attachment sites for stitch bonds 223a of bonding wires 223, enabling the connection of input/output pads 222 of chip 120 to respective leads of leadframe 110. Portions 111b are frequently referred to as tie-bars since they actually were tied to the frame of leadframe 110 before the frame has been trimmed away after the encapsulation process exposing end faces 111a of the leads.

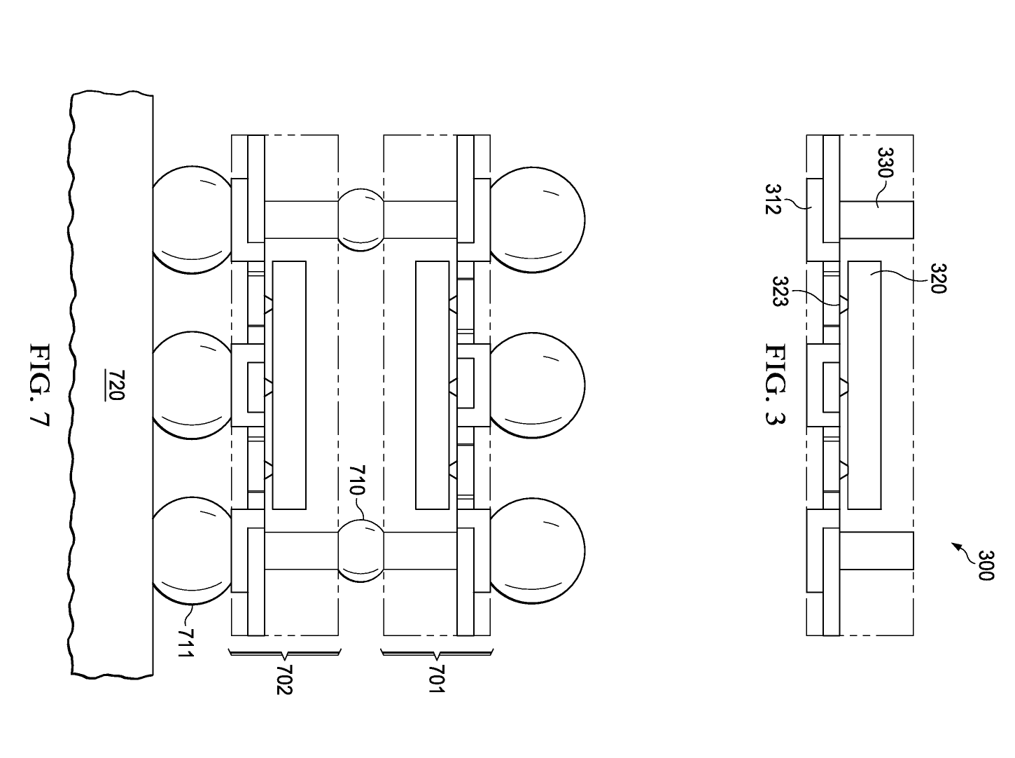

In other devices, generally designated 300 in FIG. 3, semiconductor chip 320 is flip-attached to the leadframe by metal bumps 323; preferably, bumps 323 are made of gold or copper, which are attached to the first metal of the leadframe. Flip-chip devices 300 not only have solderable terminals 312 exposed on the bottom surface, but frequently have additional terminals 330 exposed on the top surface of device 300. Terminals 330 are created by the same half-etch process of the leadframe as terminals 312, and preferably include a solderable second metal on their exposed surfaces.

FIG. 4 views, from the bottom, the exemplary leadframe of FIG. 1 without the encapsulation to illustrate the configuration of the leads of a metal leadframe for enabling an orderly two-dimensional grid array of the terminals suitable for a QFN/SON-type ball grid array device. As FIG. 4 shows, the leads of exemplary BGA leadframes may have to take unconventional configurations to function in common and non-common net assignments so that the terminals fully utilize the total leadframe area including the area under the chip. In the exemplary embodiment of FIG. 4, the BGA device has a size of 1.5 by 1.5 mm side length (designated 401) and the leadframe has 9 terminals arranged in a 3×3 matrix. Of the leadframe terminals, the four corner terminals (411, 413, 431, and 433) and two of the edge terminals (412 and 432) are connected to short leads (designated 111b in FIG. 2), which serve as wire stitch pads. On the other hand, the center terminal 422 belongs to an elongated lead 440 extending as tie-bars to opposite edges of the package, where the tie-bar ends serve as wire stitch pads. The package center area located under the chip is thus utilized as a terminal (422) with net assignment. The remaining two terminals 421 and 423 are each connected to a medium length tie-bar; these tie-bars extend to two opposite leadframe edges and serve as wire stitch pads.

In the exemplary leadframe of FIG. 4, each lead of the leadframe includes one terminal, and the lead extends from the one terminal to at least one device edge; some leads may extend to more than one device edge. Other leadframes may include leads with more than one terminal; these leads also extend to at least one device edge.

The height 450 of the terminals preserves the original thickness of the metal sheet from which the leadframe has been formed. The reduced height 451 of the leads including the tie-bars has been formed by partially etching, or half-etching, the metal of the leadframe. For many leadframes, height 451 is about 50% of height 450. Consequently, the terminals are bumps resembling a metallic cylinder or hexahedron arising from the respective lead made of the same metal, referred to as first metal. As pointed out, preferred choices for first metal include copper, aluminum, and iron-nickel alloys. Employing a half-etch process for creating the metallic terminal bumps from a metallic leadframe avoids the conventional problems of first creating through-holes through a polymeric or ceramic substrate and then filling the hole with conductive material such as a metal. The half-etch process further avoids the conventional technical issues of reducing and absorbing stress on a solder ball attached to a terminal by adding so-called under-bump metallization.

In FIG. 4, semiconductor chip 120 is attached to the leadframe in the leadframe center on the surface opposite the terminals, spanning across several adjacent leads. In the example of FIG. 4, the attachment employs an insulating adhesive film and the chip contact pads are wire-bonded to the leads. The alternative method of flip-chip attachment is indicated in FIG. 3, wherein the chip spans across several adjacent leads.

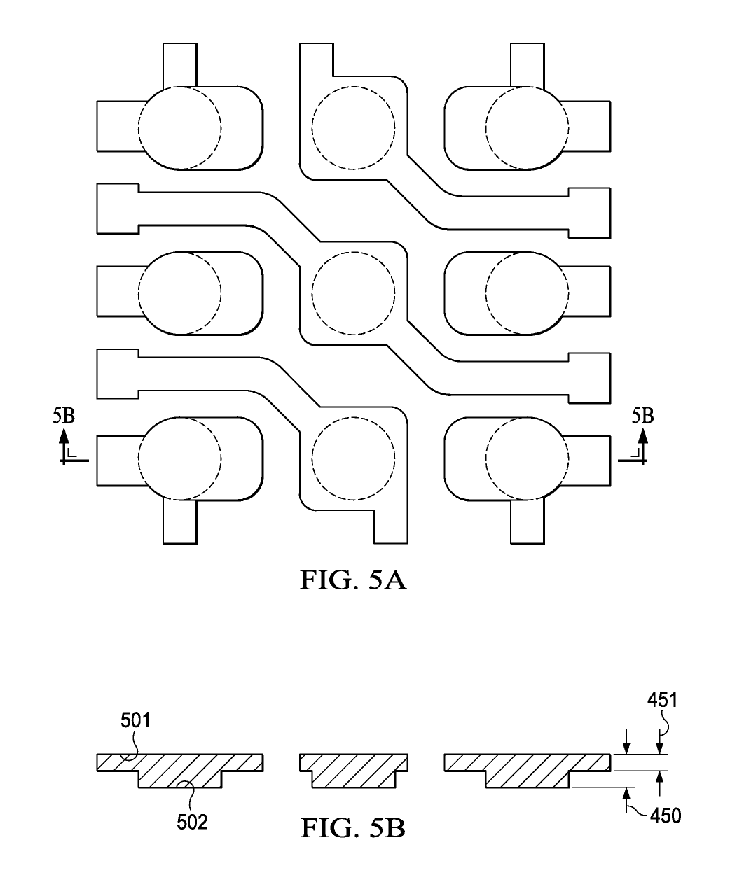

FIG. 5A views, from the top, the exemplary leadframe of FIG. 1 without the encapsulation and without the attached semiconductor chip to illustrate the configuration of the leads of a metal leadframe for enabling an orderly two-dimensional grid array of the terminals suitable for a QFN/SON-type ball grid array device. The cutaway line 5B-5B in FIG. 5A results in the cross sections of the lead portions and terminals of FIG. 5B. The top surface of the leads is designated 501 and, on the opposite side, the surface of the terminals 502. The height of the terminals, preserving the original thickness of the metal sheet from which the leadframe has been formed, is designated 450, and the height of the half-etched leads 451.

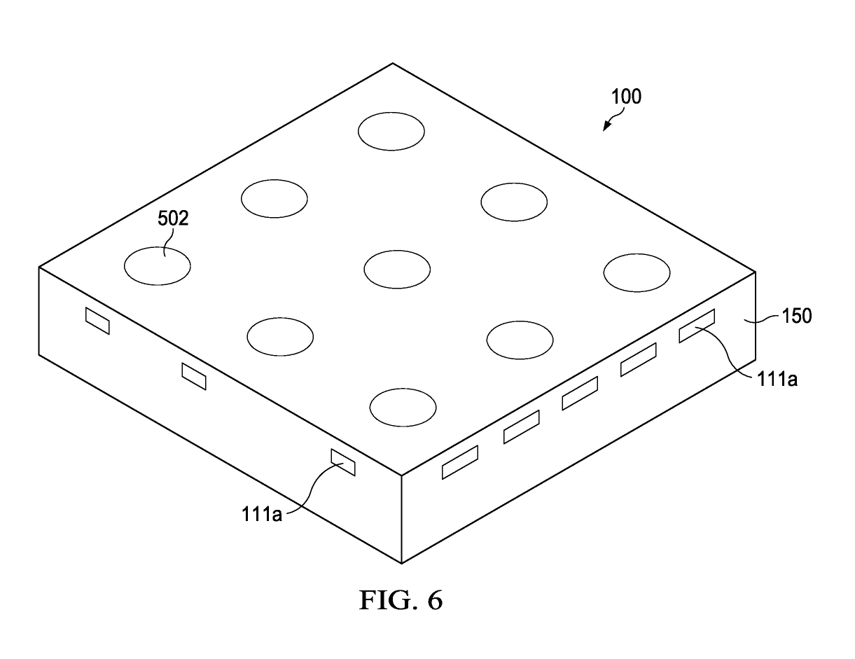

As illustrated in FIG. 6, the surfaces 502 of all terminals of exemplary device 100 and the faces 111a of all lead ends are exposed from the encapsulation compound 150 of the device. The exposed terminal surfaces 502 preferably have a metallurgical configuration to facilitate solder ball attachment. I it is preferred to achieve this configuration by depositing a layer of a solderable second metal, such as gold or tin, on the first metal of the terminal surface. Alternatively, a stack of metal layers may be deposited on the first metal, for example a layer of nickel (about 0.5 to 2.0 μthick) in contact with the first metal, a layer of palladium (about 0.01 to 0.1 μthick) in contact with the nickel, and a layer of gold (about 0.003 to 0.009 μthick) in contact with the palladium.

On the other hand, lead end faces 111a are created by the step of trimming (cutting off the frame) and thus expose the first metal of the leadframe.

In order to enhance the adhesion between metallic leadframes and polymeric encapsulation compounds, a widely used method for epoxy-based molding compounds adds design features such as indentations, grooves or protrusions to the leadframe surfaces. An example is the mechanical “dimpling” of the lead surfaces by producing patterns of indentations in the metal. Other methods modify the leadframe surface chemically by oxidizing the metal surface or by roughening the surface by chemical etching. Yet another method uses a specialized nickel plating bath to deposit a rough nickel layer.

For other devices, for which the polymeric encapsulation compound can be selected on the basis of adhesion between the polymeric formulation and specific metals, the whole leadframe may be flood-plated with a solderable second metal (see above). Reliable adhesion between the solderable metal and the encapsulation compound is achieved by the specific polymeric configuration of the selected compound.

FIG. 7 illustrates an example, how a leadframe-based ball grid array device 701 of the QFN/SON family can be stacked by solder bodies 710 to another leadframe-based BGA device 702, and the stack in turn can be attached by solder bodies 711 to a substrate or board 720. In FIG. 7, the BGA devices 701 and 702 are shown to include flip-assembled chips similar to the exemplary device depicted in FIG. 3. In other devices, analogous assemblies are possible with wire-bonded chips in at least one of the BGA devices. As FIG. 7 shows, solder connections in the device center areas are fully involved in the board assembly.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to leadframe-based BGA devices with terminals in an evenly spaced grid array, and to devices with terminals in an unevenly spaced grid array. As another example, the invention applies to devices with terminals positioned uniformly in rows and lines, and to devices with select terminal positions depleted.

It is therefore intended that the appended claims encompass any such modifications or embodiments.

We claim:

1. A device comprising:
a leadframe of a first metal; and
a terminal for input/output at the center of the device bottom.

2. The device of claim 1 further including a first plurality of terminals arranged in an orderly two-dimensional grid array extending across the device bottom area including the central area.

3. The device of claim 2 further including a second plurality of terminals extending across the device top area.

4. The device of claim 3 wherein each lead of the leadframe includes at least one terminal, and the lead extends from the at least one terminal to at least one device edge.

5. The device of claim 4 wherein the terminals and the leads are made of the first metal, whereby the metal has a greater thickness at the terminals than at the leads.

6. The device of claim 5 wherein the leads further include attachment sites for electrical connections.

7. The device of claim 6 wherein the first metal of the terminals has a solderable metallurgical surface configuration.

8. The device of claim 7 wherein the solderable metallurgical surface configuration includes a layer of a second metal.

9. The device of claim 8 further including a semiconductor chip attached to the leadframe, the chip extending across adjacent leads and being supported by the leads.

10. The device of claim 9 further including electrical connections from the chip to the leads.

11. The device of claim 10 wherein the first metal of the leads further includes surfaces having an affinity for adhering to polymeric encapsulation compounds.

12. The device of claim 11 further including a polymeric encapsulation compound packaging the leadframe with the chip and electrical connections, the compound leaving un-packaged the solderable surfaces of the terminals and the ends of the leads at the device edges.

13. The device of claim 10 further including solder balls attached to the un-packaged terminal surfaces.
